(19) United States
(12) Patent Application Publication
(10) Pub. No.: US 2013/0134505 A1
(43) Pub. Date: May 30, 2013

(54) SEMICONDUCTOR DEVICE FOR POWER AND METHOD OF MANUFACTURE THEREOF

(71) Applicant: Hitoshi KOBAYASHI, Kanagawa-ken (JP)

(72) Inventor: Hitoshi KOBAYASHI, Kanagawa-ken (JP)

(73) Assignee: KABUSHIKI KAISHA TOSHIBA, Tokyo (JP)

(21) Appl. No.: 13/605,885

(22) Filed: Sep. 6, 2012

(30) Foreign Application Priority Data
Nov. 29, 2011 (JP) P2011-259851

(51) Int. Cl. H01L 29/78; H01L 21/336

(52) U.S. Cl. 257/330; 438/270; 257/E29.262; 257/E21.41

(57) ABSTRACT

According to one embodiment, a semiconductor device for power is provided with a first conductive type a first semiconductor layer, a field insulating film, a field plate electrode, a first insulating film, an electric conductor, a second insulating film, a gate insulating film, and a gate electrode. The field plate electrode is installed in a trench of the first semiconductor layer over the field insulating film. The first insulating film is formed on the field plate electrode and encloses the field plate electrode along with the field insulating film. The electric conductor is formed on the first insulating film and is insulated from the field plate electrode. The gate electrode is installed on the upper end of the field insulating film, adjacently makes contact with the electric conductor via the second insulating film, and is installed in the trench over the gate insulating film.

### CROSS-REFERENCE TO RELATED APPLICATION

This application is based upon and claims the benefit of priority from Japanese Patent Application No. 2011-259851, filed Nov. 29, 2011; the entire contents of which are incorporated herein by reference.

### FIELD

Embodiments described herein relate to a semiconductor device for power and its manufacturing method.

### BACKGROUND

Semiconductor devices for power (“power semiconductor devices”) are used as switching elements in power supplies for portable personal computers, electric home appliances, communication appliances, network servers, etc. These power semiconductor devices are mainly MOSFET (metal oxide semiconductor field effect transistor), but there are other transistor types, such as IGBT (insulated gate bipolar transistor) and IEGT (injection enhanced gate transistor), in accordance with other uses. In these power semiconductor devices, a low on-state resistance is desired to reduce the conduction loss while at the same time the devices typically need to provide a high withstand voltage. In addition, a low input capacitance is also desired to reduce the switching loss.

On-state resistance Ron is the sum of the resistance of the drift layer and the resistance of a channel layer. To lower resistance of the drift layer a trench gate structure is used. The trench gate structure extends deep into the drift layer and may also incorporate a field plate electrode at source potential to further lower the resistance of the drift layer, while still maintaining a desired withstand (or breakdown) voltage. Since a depletion layer is easily extended into an n type drift layer from a p type base layer by this field plate electrode, the resistance of the drift layer can be lowered while maintaining the withstand voltage.

But in addition to on-state resistance and withstand voltage requirements, switching losses in power semiconductors can also be important. Switching properties are determined by the input capacitance. Input capacitance, Ciss, is the sum of the capacitance between the gate and the source, Cgs, and the capacitance between the gate and the drain, Cgd. In a trench gate structure having a field plate electrode, the capacitance Cgd is smaller than the capacitance Cgs, and is usually negligible. However, the capacitance Cgs includes the capacitance of an insulating film between the gate electrode and the field plate electrode in addition to the capacitance of the gate insulating film between the gate electrode and the p type base layer. Thus, in the trench gate structure, the capacitance Cgs is higher than an ordinary trench gate structure without a field plate electrode. To reduce the switching loss, it is necessary to decrease the capacitance between the gate and the source, so while introduction of a field plate electrode into the trench gate structure can reduce on-state resistance this improvement will generally be at the expense of increased input capacitance and switching losses.

### DESCRIPTION OF THE DRAWINGS

FIG. 1 is a schematic cross section showing main parts of a power semiconductor device according to an embodiment.

FIG. 2 is a schematic cross section showing the main parts of a power semiconductor device according to a comparative prior art example.

FIGS. 3A and 3B are schematic cross sections showing parts of a method for manufacturing a power semiconductor device according to an embodiment.

FIGS. 4A and 4B are schematic cross sections showing parts of a method for manufacturing a power semiconductor device according to an embodiment.

FIGS. 5A and 5B are schematic cross sections showing parts of a method for manufacturing a power semiconductor device according to an embodiment.

FIGS. 6A and 6B are schematic cross sections showing parts of a method for manufacturing a power semiconductor device according to an embodiment.

FIGS. 7A and 7B are schematic cross sections showing parts of a method for manufacturing a power semiconductor device according to an embodiment.

### DETAILED DESCRIPTION

In general, a method and design is provided to reduce the capacitance between the gate and the source in a power semiconductor device by incorporating a trench electrode having a distinct field plate region and an electrical conductor region, which may be either electrically connected to the gate electrode or isolated.

An embodiment of a power semiconductor device is provided with a first conductive type first semiconductor layer, field insulating film, field plate electrode, first insulating film, electric conductor, second insulating film, gate insulating film, gate electrode, second conductive type second semiconductor layer, first conductive type third semiconductor layer, interlayer dielectric, first electrode, and second electrode.

The first semiconductor layer has a first face and a second face opposite to the first face. A field plate electrode is formed in the lower portion of a trench extending into the first semiconductor layer from the first face of the first semiconductor layer over a field insulating film formed over the walls of the trench. The upper end of the field plate electrode is recessed inwardly in the trench from the first face in the direction of the second face. A first insulating film is formed over the field plate electrode and, together with the field insulating film, encloses the field plate electrode. An electric conductor is formed in the trench, over the field insulating film and the first insulating film, extending toward the first face of the semiconductor layer, and is insulated from the field plate electrode. A second insulating film covers the electric conductor and insulates the electric conductor from the outside along with the field insulating film. A gate insulating film is formed at an upper sidewall of the trench above the upper end of the field insulating film. A gate electrode is formed on the upper end of the field insulating film, adjacently making contact with the electric conductor via the second insulating film, and is installed in the trench on the gate insulating film. A second semiconductor layer is installed on the first face of the first semiconductor layer and adjacently making contact with the gate electrode via the gate insulating film. A third semiconductor layer is selectively formed on the surface of the second semiconductor layer, adjacently making contact with the gate electrode via the gate insulating film, and has a first conductive type impurity concentration higher than the first conductive type impurity concentration of the first semiconductor layer. An interlayer dielectric is formed on the gate electrode and the electric conductor. A first electrode is electrically connected to the second face of the first semiconductor layer. A second electrode is electrically connected with the second semiconductor layer, a third semiconductor layer, and the field plate electrode.

The figures, which are adopted in this explanation of an embodiment, are schematic diagrams created for easy explanation, and the shape, dimensions, size relation, etc., of each element in the figure are not necessarily the same as those in an actual application, but can be appropriately changed in a range wherein the effects of the embodiment can be obtained. In this explanation, a first conductive type is assumed as the n type, and a second conductive type is assumed as the p type. However, respective opposite conductive types can also be adopted. Silicon is an example semiconductor material, but compound semiconductors such as SiC or GaN can also be applied. Silicon oxide is used as an example insulator material, but other insulators such as silicon nitride and silicon oxynitride can also be used. When the n type conductive type is expressed by n+, n, and n−, it is assumed that the n type impurity concentration is in decreasing order of concentration. As for the p type, similarly, it is assumed that the p type impurity concentration is in decreasing order of p+, p, and p−. A trench gate MOSFET is explained as an example power semiconductor device design, but each embodiment can also be applied to IGBT, IEGT (injection enhanced gate transistor), etc. In addition, when describing relative positions, “upper” and “lower” in this explanation mean in relation to the figures oriented as drawn.

### Embodiment 1

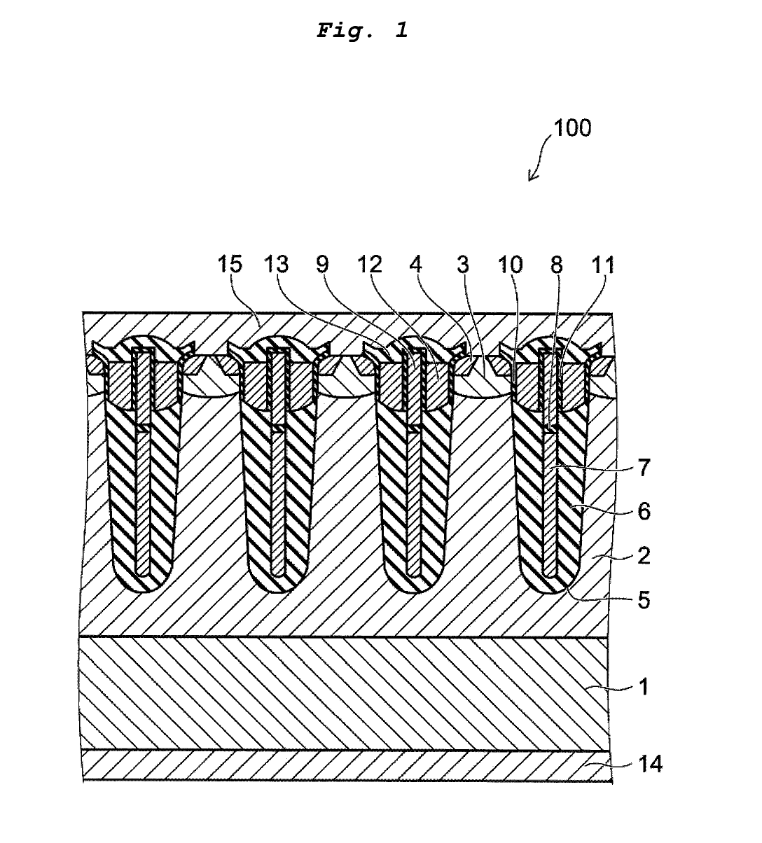

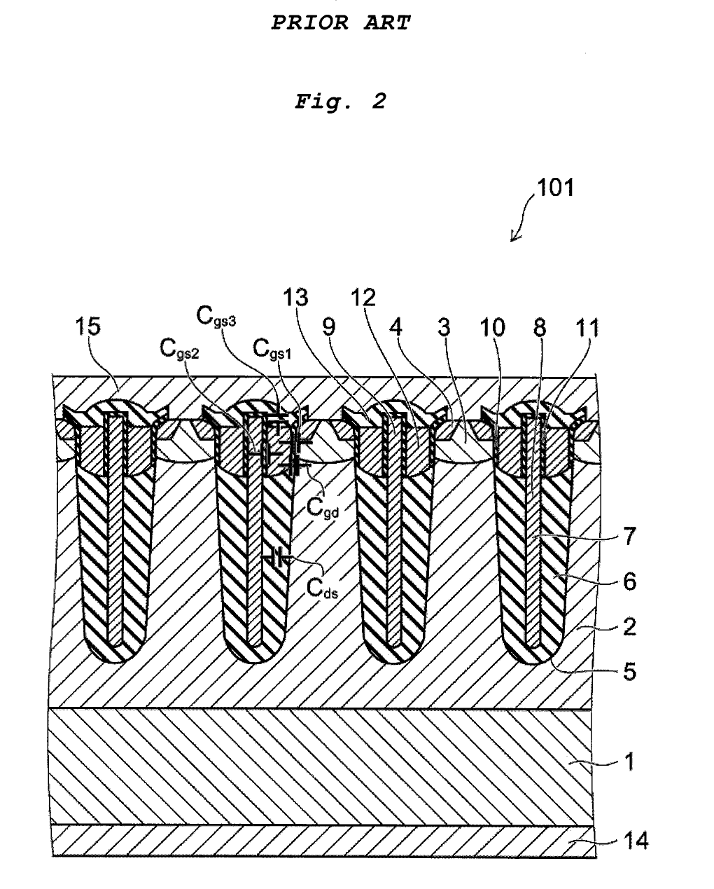

With reference to FIG. 1 and FIG. 2, a MOSFET 100 as the semiconductor device for power of an Embodiment 1 will be explained. FIG. 1 is a schematic cross section showing the main parts of the MOSFET 100 of the Embodiment 1. FIG. 2 is a schematic cross section showing the main parts of a prior art MOSFET of a comparative example.

As shown in FIG. 1, the MOSFET 100 of this embodiment is provided with an n+ type drain layer 1, n− type drift layer 2, field insulating film 6, field plate electrode 7, first insulating film 8, electric conductor 9, second insulating film 11, gate insulating film 10, gate electrode 12, p type base layer 3, n+ type source layer 4, interlayer dielectric 13, drain electrode 14, and source electrode 15. The n+ type drain layer 1, n− type drift layer 2, p type base layer 3, and n+ type source layer 4, for example, are semiconductor layers composed of silicon.

The n− type drift layer 2 has a first face and a second face opposite to the first face. The n+ type drain layer 1 is electrically connected to the second face of the n− type drift layer 2. A trench 5 is formed so that it extends from the first face of the n− type drift layer 2 into the n− type drift layer 2. The field insulating film 6 is formed in the trench 5 along the inner surface of the trench 5. The field insulating film 6 has upper ends retreated towards the second face from the first face of the n− type drift layer 2 at both opposite sidewalls of the trench 5. The field insulating film 6, for example, is silicon oxide (SiO₂), but silicon nitride (SiN), silicon oxynitride (SiNO), or alumina (Al₂O₃) can also be used. The field insulating film 6 is formed relatively thickly to reduce the electric field concentration on the interface of the tip of the trench 5 and the n−type drift layer 2 and, for example, compared with the gate insulating film 10, which will be mentioned later.

The field plate electrode 7 is formed within a recess remaining in the field insulating film 6 after formation thereof within the trench 5. In other words, the field plate electrode 7 becomes embedded within the field insulating film 6. The field plate electrode may be composed of a conductive material 7. For example, a conductive polysilicon is used. Instead of the polysilicon, tungsten or titanium silicide, etc., can also be used.

The first insulating film 8 is formed over the field plate electrode 7 and, along with the field insulating film 6, encloses the field plate electrode 7. The first insulating film 8 can be composed of silicon oxide similarly to the field insulating film 6, but other insulating films such as silicon nitride, silicon oxynitride, or alumina can be used.

The electric conductor 9 is formed within the trench 5 and extends from the first insulating film 8 toward the first face of the n− type drift layer 2, and is insulated from the field plate electrode 7 by the first insulating film 8. The electric conductor 9 is electrically connected with the gate electrode 12, in a region not shown in the figure. Alternatively, the electric conductor 9 may be completely insulated within the trench 5 by the first insulating film 8, field insulating film 6, and second insulating film 11 so that a fixed potential cannot be rendered thereon, thereby forming a floating state. The electric conductor 9 can be composed of the same material as that of the field plate electrode 7. For example, it may be a conductive polysilicon, but different materials may also be used.

The second insulating film 11 caps or overlies the portion of the electric conductor 9 extending from the field insulating film 6 and thereby electrically insulates the electric conductor 9 (except for the case wherein the electric conductor 9 is electrically connected to the gate electrode 12 elsewhere). The gate insulating film 10 is formed on the sidewall of the trench 5 in the upper part thereof and covers the walls of the trench from the upper end of the field insulating film 6 to the first surface of the drift layer 2. The second insulating film 11 and the gate insulating film 10 can also be insulators such as silicon oxide, silicon nitride, silicon oxynitride, or alumina, similarly to the field insulating film 6.

The gate electrode 12 is formed on the remaining, exposed, upper end of the field insulating film 6 between the second insulating film 11 and the gate insulating film 10 within trench 5, and adjacently makes contact with the electric conductor 9 via the second insulating film 11. The gate electrodes 12 are a pair of gate electrodes 12 that are respectively formed on opposite sides of the electric conductor. The gate electrode 12 can be composed of the same material as that of the field plate electrode 7. For example, the material may be a conductive polysilicon, but different materials can also be used.

The p type base layer 3 is formed, such as by implanting p type dopants in the first face of the n−type drift layer 2 and adjacently makes contact with the gate electrode 12 via the gate insulating film 10. The p type base layer 3 may be considered to be formed in pairs, such that the electric conductor 9 and a pair of gate electrodes 12 in a trench are sandwiched between p type base layers 3 to either side of the trench. The bottom of the p type base layer 3 is formed on the first face of the n−type drift layer 2 from the bottom of the gate electrode 12. In other words, the gate electrode 12 straddles the n+ type source layer 4 to the n− type drift layer 2 on the p type base layer 3.

The n+ type source layer 4 is selectively formed on the first face of the n− type drift layer 2 such as by dopant implantation, that is, the upper surface of the p type base layer 3 and adjacently makes contact with the gate electrode 12 via the gate insulating film 10. The n+ type source layer 4 has an n type impurity concentration higher than the n type impurity concentration of the n− type drift layer 2. The n+ type source layer 4 are also constituted in pairs, such that an electric conductor 9 and a pair of gate electrodes 12 are sandwiched between an n+ type source layer 4 to either side of a trench 5.

The interlayer dielectric 13 is formed on the gate electrode 12 and the electric conductor 9, and the interlayer dielectric 13 can be an insulator such as silicon oxide, silicon nitride, silicon oxynitride, or alumina similarly to the field insulating film 6. The drain electrode 14 is electrically connected to the second face of the n− type drift layer 2 via by the n+ type drain layer 1. The source electrode 15 is electrically connected with the p type base layer 3, n+ type source layer 4, and field plate electrode. The source electrode 15 is insulated from the gate electrode 12 and the electric conductor 9 by the interlayer dielectric 13. The drain electrode 14 and the source electrode 15 are formed of a metallic material such as copper or aluminum.

The operation and advantages of the MOSFET 100 of this embodiment will be explained through a comparison with a MOSFET 101 of a comparative example. FIG. 2 shows the MOSFET 101 of the comparative example. The MOSFET 101 of the comparative example is a structure in which the electric conductor 9 and the field plate electrode 7 are connected and integrated, without a separating first insulating film 8 in the MOSFET 100 of FIG. 1. In other words, in the MOSFET 101, the field plate electrode 7 is sandwiched by the second insulating film 11 and the gate electrodes 12, but there is no insulating layer between upper and lower portions of the trench electrode (i.e., field plate electrode 7 in FIG. 2).

In the MOSFET 101 of the comparative example, in a state in which a positive voltage to the source electrode 15 is applied to the source electrode 14, if a positive voltage exceeding a threshold to the source electrode 15 is applied to the gate electrode 12, a channel layer is formed on the surface of the p type base layer adjacent to the gate electrode 12 via the gate insulating film 10, setting the MOSFET 101 to an On-state. At that time, electrons flow to the drain electrode 14 via the n+ type source layer 4, channel layer in the p type base layer 3, n− type drift layer 2, and n+ type drain layer 1 from the source electrode 15. Therefore, a drain current flows in the direction opposite to the electrons.

If a voltage lower than the threshold is applied to the gate electrode, the channel layer is lost, and the MOSFET 101 is set to an off-state. At that time, the voltage between the drain and the source rises, and a depletion layer is widened from the p type base layer 3 to the n− type drift layer 2. To secure a high withstand voltage, it is necessary to sufficiently extend the depletion layer by raising the resistance value of the n− type drift layer 2. However, if the resistance value of the n− type drift layer 2 rises, the on-resistance of the MOSFET 101 increases.

Accordingly, the field plate electrode 7 is installed in the gate trench to lower the resistance value of the n− type drift layer 2 and to sufficiently widen the depletion layer from the p type base layer 3 to the n− type drift layer 2. In other words, to extend the depletion layer from the p type base layer 3 into the n− type drift layer 2 as much as the portion required for the withstand voltage, the trench 5 is installed so that it is extended sufficiently deep in the n− type drift layer 2 from the bottom of the p type base layer 3. The gate electrode 12 is formed up to a depth required for the formation of a channel for connecting the n+ type source layer 4 and the n− type drift layer 2 in the p type base layer 3. The field plate electrode 7 extends at least toward the drain electrode 14 in the trench 5 via the field plate insulating film 6 from the lower side of the gate electrode 12.

With this structure, a voltage between the drain and the source is applied between the drain electrode 14 and the field plate electrode 7. For this reason, when the MOSFET 101 is in an off-state, the depletion layer is extended and coupled into the n− type drift layer 2 from the adjacent trench 5. Therefore, since the depletion layer extends easily from the p type base layer 3 toward the n− type drift layer 2, even if the n− type drift layer 2 has low resistance, the withstand voltage of the MOSFET 101 is improved.

However, in the MOSFET 101 of the comparative example, the gate electrode 12 sandwiches the field plate electrode 7 via the second insulating film 11 in the trench 5. Therefore, as shown in FIG. 2, the capacitance Cgs2 of the second insulating film 11 sandwiched by the gate electrode 12 and the field plate electrode 7 is generated.

The input capacitance, Ciss, of the MOSFET 101 of the comparative example is the sum of the capacitance, Cgs, between the gate and the source and the capacitance, Cgd, between the gate and the drain. In addition, as shown in FIG. 2, the capacitance Cgs is the sum of the capacitance, Cgs1, of the gate insulating film 10 sandwiched by the gate electrode 12 and the p type base layer, the capacitance, Cgs2, of the second insulating film 11 sandwiched by the gate electrode 12 and the field plate electrode 7, and the capacitance, Cgs3, of the interlayer dielectric 13 sandwiched by the gate electrode 12 and the source electrode 15.

Here, since the interlayer dielectric 13 is thick, Cgs3 is negligible, compared with the other capacitances. In addition, the capacitance Cgd is also negligible, compared with the other capacitances, because the overlapping area of the gate electrode 12 and the n− type drift layer 2 is narrow. Therefore, Cgs1 and Cgs2 are dominant in the input capacitance Ciss of the MOSFET 101 of the comparative example.

In contrast, MOSFET 100 in which the field plate electrode 7 in the MOSFET 101 (as depicted in FIG. 2) is divided into the electric conductor 9 and the field plate electrode 7 by the first insulating film 8 (as depicted in FIG. 1) enables the high withstand voltage desired, without significant negative impact on the capacitance Ciss. The electric conductor 9 is insulated and separated from the field plate electrode 7 by the first insulating film 8 and has the same potential as that of the gate electrode 12. For this reason, in the MOSFET 100, the capacitance, Cgs2, between the gate and the source of the second insulating film 11 sandwiched by the electric conductor 9 and the gate electrode 12 is slight.

From this fact, the capacitance, Cgs1, between the gate and the source of the gate insulating film 10 sandwiched by the gate electrode 12 and the p type base layer 3 is dominant in the input capacitance, Ciss, of the MOSFET 100. As mentioned above, the input capacitance of the MOSFET 100 can be made lower than the input capacitance of MOSFET 101 by reducing the capacitance Cgs2 between the gate and the drain of the second insulating film 11 sandwiched by the electric conductor 9 and the gate electrode 12.

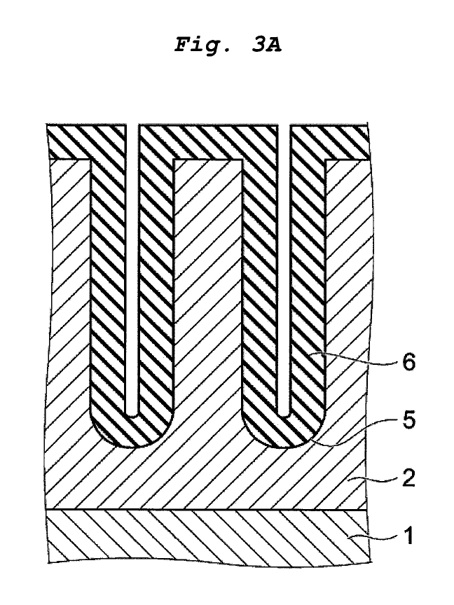

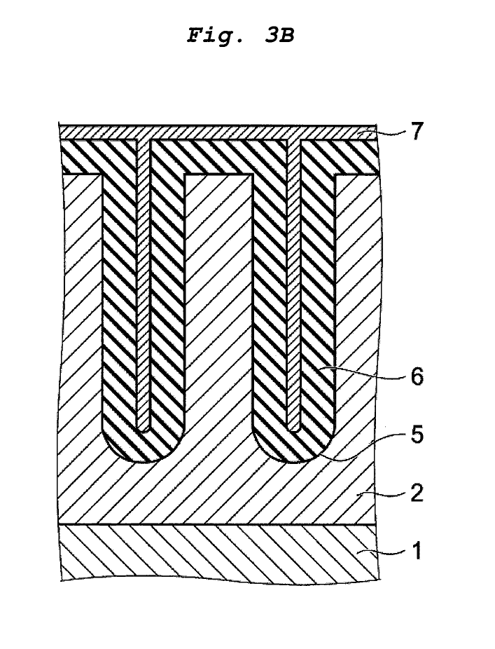

Next, the method for manufacturing the MOSFET 100 will be explained. FIG. 3A to FIG. 7B are schematic cross sections showing parts of the method for manufacturing the MOSFET 100 of this embodiment.

As shown in FIG. 3A, first, the trench 5 is formed on the first face of the n− type drift layer 2 having the n+ type drain layer 1 on the second face by a RIE (reactive ion etching). The depth of the trench 5 is determined so that the depletion layer is extended up to a prescribed depth in accordance with the desired withstand voltage of the MOSFET 100. For example, when the withstand voltage is about 100 V, the trench 5 is formed so that the depth of the trench 5 from the first face of the n− type drift layer 2 is about 6 μm. The higher the withstand voltage, the deeper the trench 5 to be formed.

After forming the trench 5, the field insulating film 6 is formed on the first face of the n− type drift layer 2 and the entire inner surface of the trench 5. The field insulating film 6, for example, is silicon oxide and can be formed by a thermal oxidation method to oxidize the adjacent surface of the drift layer 2, or by a CVD (chemical vapor deposition) method to deposit an additional insulating material over the drift layer 2 material forming the trench 5 wall. The field insulating film 6 may be composed of silicon nitride, silicon oxynitride, or alumina when formed by the CVD method.

Next, as shown in FIG. 3B, conductive polysilicon 7 used to form the electrodes 7, 9 is formed by the CVD method so that it is embedded in the trench 5 over the field insulating film 6. The conductive polysilicon 7, for example, includes p type impurities, but n type impurities can also be included.

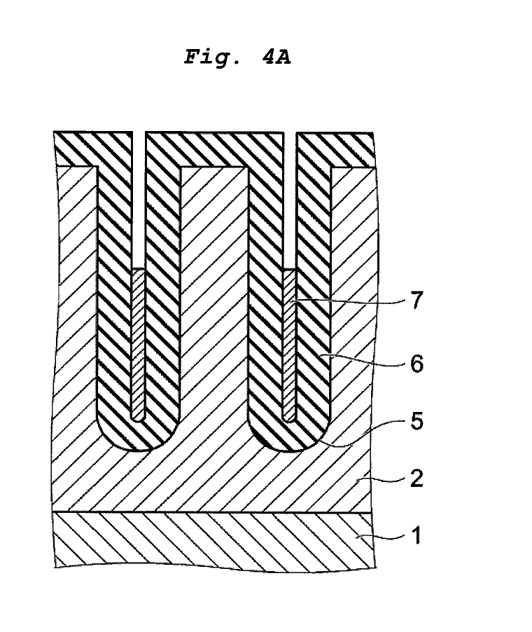

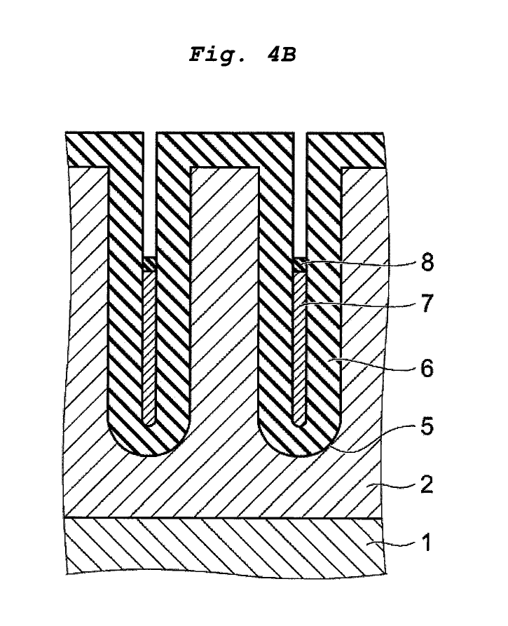

Next, as shown in FIG. 4A, the polysilicon 7 is, for example, etched by the CDE (chemical dry etching) method to shorten the electrode thereon in the field insulating film and thereby recess it in the trench. As a result, the field plate electrode 7 is formed in the trench 5 over the field insulating film 6.

Next, as shown in FIG. 4B, the first insulating film 8 is formed by the thermal oxidation method or CVD method over the exposed upper surface of the field electrode 7 in the field insulating film 6. The first insulating film 8, for example, is silicon oxide, but other insulators can also be used similarly to the field insulating film 6.

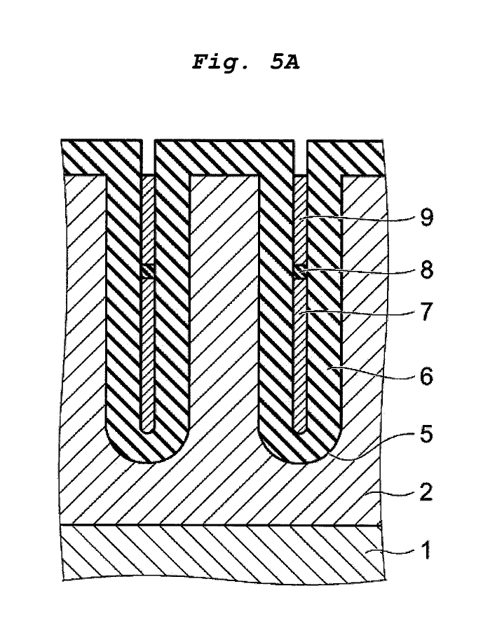

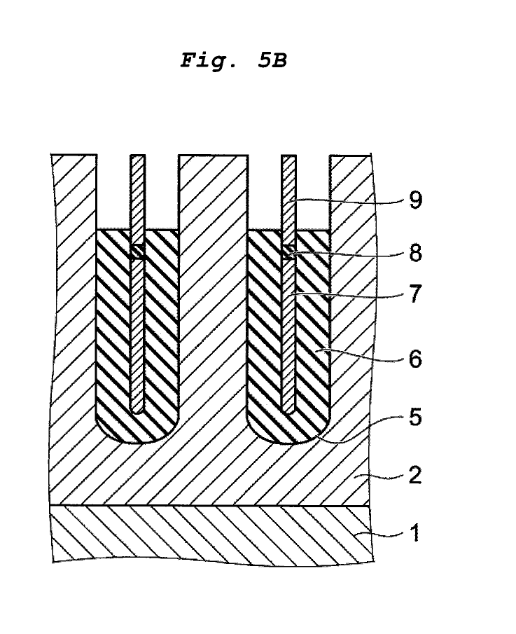

Next, conductive polysilicon 9 is formed by the CVD method so that it is deposited into the trench 5 within the field insulating film 6. The conductive polysilicon 9, similarly to the field plate electrode 7, includes p type impurities, but n type impurities can also be included. Referring to FIG. 5A, conductive polysilicon 9 is, for example, then etched by the CDE method so that its upper end is about the same height as that of the first face of the n− type drift layer, thereby forming the electric conductor 9.

Next, as shown in FIG. 5B, the field insulating film 6 is etched by, for example, wet-etching the film with a hydrogen fluoride (HF) system etching solution so that the field insulating film 6 is etched off of the first face of the n− type drift layer 2 and a portion of the field insulating film 6 extending inwardly of the trench from the first face of the n− type drift layer is etched away to near the location of the first insulating film 8 within the trench. In this wet etching, the HF etchant is selected to be highly selective to an insulating film, such that the etchant provide a very low etch rate on the electric conductor 9, so the field insulating film 6 is selectively etched. As a result, the electric conductor 9 is exposed from the field insulating film 6 and extends toward the first face of the n− type drift layer 2, and the trench wall, composed of the n− type drift layer material, is exposed from the top of the remaining field insulating film 6 in the trench 5 to the first surface of the n−type doped drift layer.

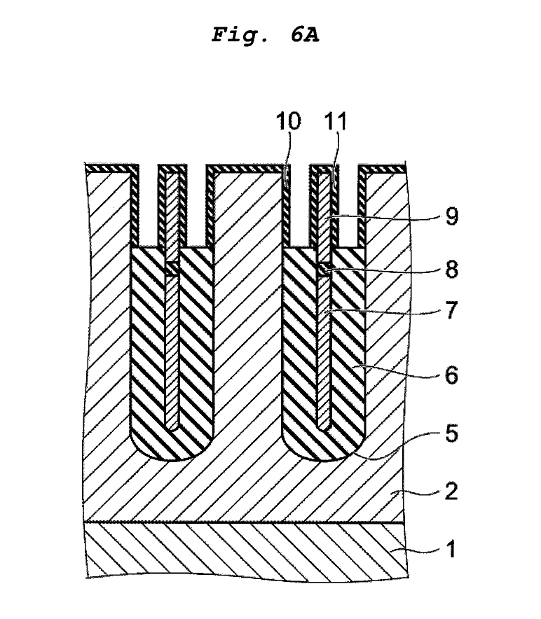

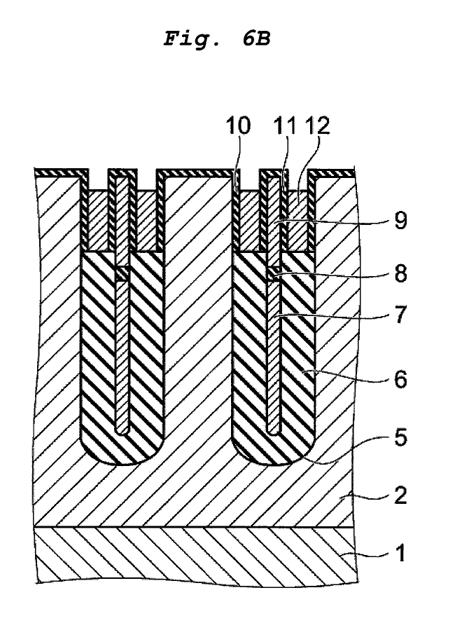

Next, as shown in FIG. 6A, silicon oxide, for example, is grown in situ by a thermal oxidation method on the exposed n−type drift layer on the exposed trench 5 wall surface and the exposed surface of the electrical conductor 9, as well as the first surface of the n− type drift layer. The silicon oxide can also be formed by the CVD method, but, the film layer so formed need be thinner than the adjoining remaining portion of the field insulating film 6. As a result, the second insulating film 11, which insulates the electric conductor 9, and the gate insulating film 10, which covers the sidewall of the trench 5 and is connected with the field insulating film 6, may be simultaneously formed by the same process.

Next, as shown in FIG. 6B, similarly to the formation of the field plate electrode 7 and the electric conductor 9, conductive polysilicon 12 is deposited in the trench 5 between the gate insulating film 10 and the second insulating film 11, as well as over the portion of the insulating film grown over the first surface of the n− type drift layer previously grown on the upper surface of the n−type drift layer, by the CVD method. Thereafter, the polysilicon 12 is etched back to from a recess in the trench 5, such that the top of the remaining below the position of the adjoining first face of the n− type drift layer 2. The remaining polysilicon in the trench forms the gate electrodes 12 is formed on the upper end of the field insulating film 6, adjacently makes contact with the electric conductor via the second insulating film 11, and is in contact with the gate insulating film 10.

Here, in the MOSFET 100 of this embodiment, the electric conductor 9 is extends from the field insulating film 6 and toward the first face of the n− type drift layer 2. As a result, the gate electrode 12 is divided into two parts in the trench 5 in the horizontal direction by the electric conductor 9. In other words, the width in the trench into which the polysilicon 12 is embedded to form the gate electrode 12 is much narrower, compared with the case wherein the electric conductor 9 is not present.

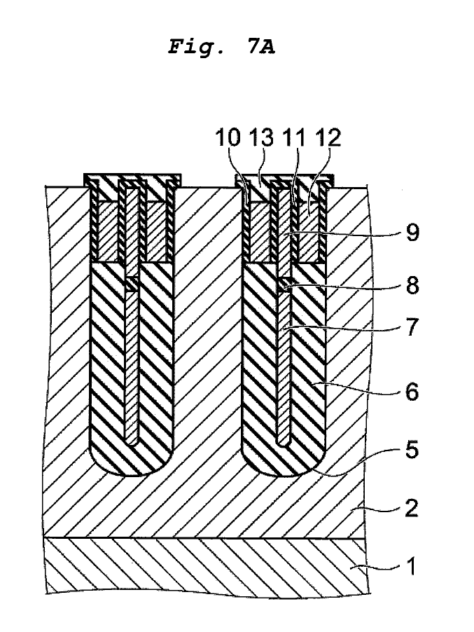

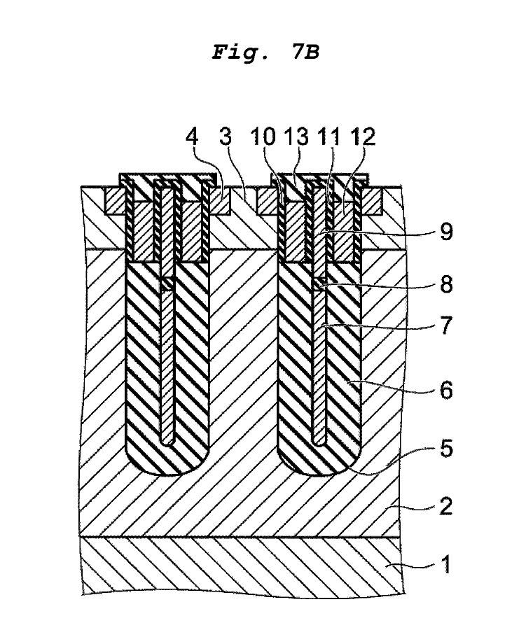

Next, as shown in FIG. 7A, silicon oxide interlayer dielectric 13 is formed by depositing silicon oxide as a blanket film over the thermal oxide previously grown on the first surface of the n− type layer, the thermal oxide in the trench not covered by the gate electrodes 12, and the upper portion of the gate electrodes 12 using a the CVD. The silicon oxide may also be formed by thermal oxidation on the gate electrode 12 material. Next, using a mask not shown in the figures, the silicon oxide 13 is etched by the RIE method, removing the silicon oxide, and the thermal oxide layers from the first surface of the n− type layer, leaving an interlayer dielectric 13 overlying only the trench 5, and the gate electrodes 12 and electric conductor 9. The interlayer dielectric 13, along with the field insulating film 6, gate insulating film 10, and second insulating film 11, encapsulates the gate electrode s 12. From an opening in the interlayer dielectric 13, not shown in the figure the gate electrode 12 is connected to a gate wiring not shown in the figure. In addition, also not shown in the figures, through etching, an opening is etched through the interlayer dielectric 13 and the gate insulating film 10 is formed, and the first face of the n− type drift layer 2 between the adjacent trenches 5 is exposed via the opening.

Next, p type impurities are ion-implanted, using the interlayer dielectric 13 formed on the gate electrode 12 as a mask, forming the p type base layer 3 on the first layer of the n− type drift layer between the adjacent trenches 5 as shown in FIG. 7B. The p type base layer 3 adjacently makes contact with the gate electrode 12 via the gate insulating film 10. Next, using a mask not shown in the figure, n type impurities are ion-implanted, selectively forming the n+ type source layer 4 on the upper surface of the p type base layer 3 as shown in FIG. 7B. The dose amount of the ion implantation is set so that the n type impurity concentration of the n+ type source layer 4 is higher than the n type impurity concentration of the n− type drift layer 2. The n+ type source layer 4 also adjacently makes contact with the gate electrode 12 via the gate insulating film 10.

Next, the drain electrode 14 (FIG. 1) is formed so that it is electrically connected to the n+ type drain layer 2, although it is not shown in the figure. The source electrode 15 (FIG. 1) is formed so that it is electrically connected to the p type base layer 3 and the n+ type source layer 4 via the opening part of the interlayer dielectric 13. In an area not shown in the figure, the source electrode 15 is electrically connected with the field plate electrode 7.

The MOSFET 100 of this embodiment shown in FIG. 1 is manufactured by applying the processes explained above. Similar effects may be obtained in IGBT or IEGT devices using similar methods.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a trench gate structure formed on a substrate, the trench gate structure comprising:
a trench formed in a semiconductor layer of first conductivity type having a sidewall;
a field insulating film covering the bottom of the trench and portions of the trench sidewall extending from the bottom of the trench, the field insulating film providing a recess therein extending inwardly of, and spaced from the trench sidewall, by the field insulating film;
a field plate electrode within the trench and extending from the base of the recess and terminating therein;
a first insulating film received in the recess and in contact with the field plate electrode;
an electrical conductor extending from the first insulating film at a position within the recess, and to a position outwardly of the recess, the electrical conductor having opposed sides facing opposed sides of the trench;
a second insulating film covering the electrical conductor where it is not in contact with the first insulating film or the field insulating film, and the portion of the trench sidewall not covered by the field insulating film; and
a gate electrode disposed within the trench and contacting the second insulating film on both sides of the electrical conductor.

2. The semiconductor device of claim 1, wherein the electrical conductor is electrically connected to an adjacent gate.

3. The semiconductor device of claim 1, wherein the field plate electrode is electrically isolated.

4. The semiconductor device of claim 1, wherein the first insulating film comprises silicon oxide, silicon nitride, or silicon oxynitride.

5. The semiconductor device of claim 1, wherein the first insulating film is formed by chemical vapor deposition.

6. The semiconductor device of claim 1, wherein the electrical conductor comprises polysilicon.

7. The semiconductor device of claim 1, wherein the electrical conductor is a material that has lower etch rate than the field insulating film when exposed to hydrogen fluoride.

8. The semiconductor device of claim 1, wherein the first semiconductor layer is doped with n−type dopant.

9. The semiconductor device of claim 1, wherein the trench gate structure is part of a MOSFET device.

10. A power semiconductor device, comprising:
a first conductive type first semiconductor layer having a first face and a second face opposite to the first face;
a field insulating film that is installed in a trench extending into the first semiconductor layer from the first face of the first semiconductor layer, the trench terminating in a lower end that is spaced from the second face of the first semiconductor layer;
a field plate electrode positioned with the field insulating film in the trench and extending from a first position adjacent to the terminus of the trench, and spaced therefrom by interposed field insulating film, to a second position within the trench spaced from the first position of the field plate electrode;
a first insulating film positioned over the second position of the field plate electrode and, along with the field insulating film, surrounds the field plate electrode;
an electric conductor that is installed on the first insulating film, and extend therefrom in the direction of first face of the first semiconductor layer, and is insulated from the field plate electrode by the first insulating film;
a second insulating film formed over the electric conductor and, along with the field insulating film, encloses the electric conductor;
a gate insulating film over the an upper sidewall of the;
a gate electrode that located over the field insulating film in the trench, adjacently making contact with the electric conductor via the second insulating film and with the first semiconductor layer through the gate insulating film, the electrode terminating within the trench;
a second conductivity type second semiconductor layer that is installed on the first face of the first semiconductor layer and adjacently makes contact with the gate electrode via the gate insulating film;
a first conductivity type third semiconductor layer that is selectively installed on the upper surface of the second semiconductor layer, adjacently makes contact with the gate electrode via the gate insulating film, and has a first conductive type impurity concentration higher than the first conductive type impurity concentration of the first semiconductor layer;
an interlayer dielectric located on the gate electrode and the electric conductor;
a first electrode electrically connected to the second face of the first semiconductor layer; and
a second electrode electrically connected with the second semiconductor layer, the third semiconductor layer, and the field plate electrode,
wherein
the electric conductor is electrically connected with the gate electrode;
the first insulating film is installed on the second face of the first semiconductor layer from the upper end of the field insulating film;
the bottom of the second semiconductor layer is installed on the first face of the first semiconductor layer from the upper end of the field insulating film;
the upper end of the field insulating film is a pair of upper ends that sandwiches the electric conductor;
the gate electrode includes a pair of gate electrodes that sandwich the electric conductor;
the second semiconductor layer and the third semiconductor layer are a pair of second semiconductor layers and a pair of third semiconductor layers that sandwich the electric conductor and the one pair of gate electrodes; and
a second conductive type fourth semiconductor layer is further installed between the first semiconductor layer and the first electrode.

11. A method for manufacturing a semiconductor device, comprising the steps of:
forming a trench extending from a first face of a first semiconductor layer into the first semiconductor layer;
forming a field insulating film so that the inner surface of the trench is covered;
forming a field plate electrode in the trench over the field insulating film;
recessing the field plate electrode layer into the trench from the first face of the first semiconductor layer;
forming a first insulating film on the field plate electrode;
forming an electric conductor in the trench above the first insulating film and the field insulating film;
etching the field insulating film so that the upper end of the field insulating film retreats from the first face of the first semiconductor layer towards the second face of the first semiconductor layer;
forming a second insulating film that covers the electric conductor exposed by the process of etching the field insulating film;
forming a gate insulating film on an upper sidewall of the trench exposed by the process of etching the field insulating film; and
forming a gate electrode in the trench in regions left unfilled after the forming of the gate insulating film.

12. The method for manufacturing a semiconductor device according to claim 11, further comprising:
forming a second semiconductor layer of second conductivity type on the first face of the first semiconductor layer, the second semiconductor layer adjacent to the gate electrode via the gate insulating film;
forming a third semiconductor layer of first conductivity type on the upper surface of the second semiconductor layer to be adjacent to the gate electrode via the gate insulating film, the third semiconductor layer;
forming an interlayer dielectric on the gate electrode and the electric conductor;
forming a first electrode electrically connected to the second face of the first semiconductor layer; and
forming a second electrode electrically connected to the second semiconductor layer, the third semiconductor layer, and the field plate electrode.

13. The method for manufacturing a semiconductor device according to claim 11, wherein
the first insulating film is formed by thermal oxidation.

14. The method for manufacturing a semiconductor device according to claim 11, wherein
the first insulating film is formed by chemical vapor deposition.

15. The method for manufacturing a semiconductor device according to claim 11, wherein
the gate insulating film and the second insulating film are formed at the same time.

16. The method for manufacturing a semiconductor device according to claim 11 further comprising forming electrical connections between the electrical conductor and the gate electrode.

17. The method for manufacturing a semiconductor device according to claim 11, wherein
the process for forming the electric conductor includes embedding a conductive polysilicon into the trench.

18. The method for manufacturing a semiconductor device according to claim 11, wherein the field insulation film is etched using hydrogen fluoride.

19. The method for manufacturing a semiconductor device according to claim 11, wherein the field plate electrode is recessed using chemical dry etching.

20. The method for manufacturing a semiconductor device of claim 11, wherein the field plate electrode and the electric conductor have the same width.
